(19) United States
(12) Patent Application Publication
(10) Pub. No.: US 2016/0079374 A1
(43) Pub. Date: Mar. 17, 2016

(54) SEMICONDUCTOR DEVICE AND MANUFACTURING METHOD THEREOF

(71) Applicant: KABUSHIKI KAISHA TOSHIBA, Tokyo (JP)

(72) Inventor: HIDEKI OKUMURA, Nonoichi Ishikawa (JP)

(21) Appl. No.: 14/624,492

(22) Filed: Feb. 17, 2015

(30) Foreign Application Priority Data
Sep. 16, 2014 (JP) 2014-188292

(51) Int. Cl. H01L 29/40; H01L 29/06; H01L 29/423; H01L 21/02; H01L 29/78; H01L 29/66

(52) U.S. Cl. CPC H01L 29/407; H01L 29/7813; H01L 29/66666; H01L 29/66734; H01L 29/401; H01L 29/4236; H01L 21/0223; H01L 29/0696; H01L 21/02255

(57) ABSTRACT

A manufacturing method of a semiconductor device includes forming a first electrode on a lower portion of a trench that is formed on a semiconductor layer and having a first insulating film between the first electrode and the semiconductor layer; forming a second insulating film that covers an inner surface of an upper portion of the trench, forming a resist film that extends into the upper portion of the trench on the second insulating film, removing the second insulating film between the resist film and a side wall of the trench to leave a portion of the second insulating film on the first electrode, forming a third insulating film on a side wall of an upper portion of the trench, and forming a second electrode on the first electrode in an inner portion of the second insulating film.

### CROSS-REFERENCE TO RELATED APPLICATION

This application is based upon and claims the benefit of priority from Japanese Patent Application No. 2014-188292, filed Sep. 16, 2014, the entire contents of which are incorporated herein by reference.

### FIELD

Embodiments described herein relate generally to a semiconductor device and a manufacturing method thereof.

### BACKGROUND

A semiconductor device which is used for electric power control or the like includes a metal oxide semiconductor field effect transistor (MOSFET). A MOSFET for electric power control has a trench gate structure including a gate electrode and a field plate electrode (FP electrode). In the trench gate structure, the gate electrode and the FP electrode are disposed on an insulating film in an inner portion of a trench provided in a semiconductor layer. The FP electrode is disposed, for example, below the gate electrode and in a lower portion of the trench. In such a semiconductor device, it is desirable that the thickness of the insulating film between the gate electrode and the FP electrode is considerably large in order to reduce parasitic capacitance between the gate electrode and the FP electrode. However, if the insulating film between the gate electrode and the FP electrode is concurrently formed during formation of a gate oxide film, the thickness of the insulating film is limited based on the required thickness of the gate oxide film. In addition, if the insulating film is separately formed after forming the gate oxide film, the manufacturing process becomes complicated and manufacturing costs are increased because additional deposition, masking, and etching steps are then required to form the insulating film.

### DESCRIPTION OF THE DRAWINGS

FIG. 1 is a schematic cross-sectional view depicting a semiconductor device according to an embodiment.

FIG. 2A to FIG. 5C are schematic cross-sectional views depicting a manufacturing process of the semiconductor device according to the embodiment.

FIG. 6A to FIG. 6C are schematic cross-sectional views depicting a manufacturing process of a semiconductor device according to a modification of the embodiment.

### DETAILED DESCRIPTION

An embodiment provides a semiconductor device and a manufacturing method thereof which are capable of reducing a parasitic capacitance of a gate electrode.

In general, according to one embodiment, a manufacturing method of a semiconductor device includes: forming a first electrode in a lower portion of a trench extending inwardly of a semiconductor layer and on a first insulating film disposed between the first electrode and the semiconductor layer; forming a second insulating film on an inner surface of an upper portion of the trench; forming a resist film in the upper portion of the trench and on the second insulating film; removing the second insulating film between the resist film and a side wall of the trench to leave a portion of the second insulating film on the first electrode; forming a third insulating film on a side wall of an upper portion of the trench; and forming a second electrode on the first electrode in an inner portion of the trench and over a portion of the second insulating film.

Hereinafter, the description of an embodiment is given with reference to the drawings. Like reference numerals are given to similar elements in the drawings and a detailed description thereof is omitted for brevity. Any elements that differ from previously described elements will be described as appropriate. The drawings are schematic or conceptual and thus a relationship between a thickness and a width of each element, as well as a dimensional ratio between elements are not necessarily the same as an actual device. In addition, even if the drawings represent the same elements, dimensions and ratios are expressed differently according to drawings.

Further, configurations of the respective elements are described by using an X axis, a Y axis, and a Z axis which are indicated in the respective drawings. The X axis, the Y axis, and the Z axis are mutually orthogonal and are expressed as an X direction, a Y direction, and a Z direction, respectively. The Z direction may be described as the upper side and an opposite direction thereof may be described as the lower side.

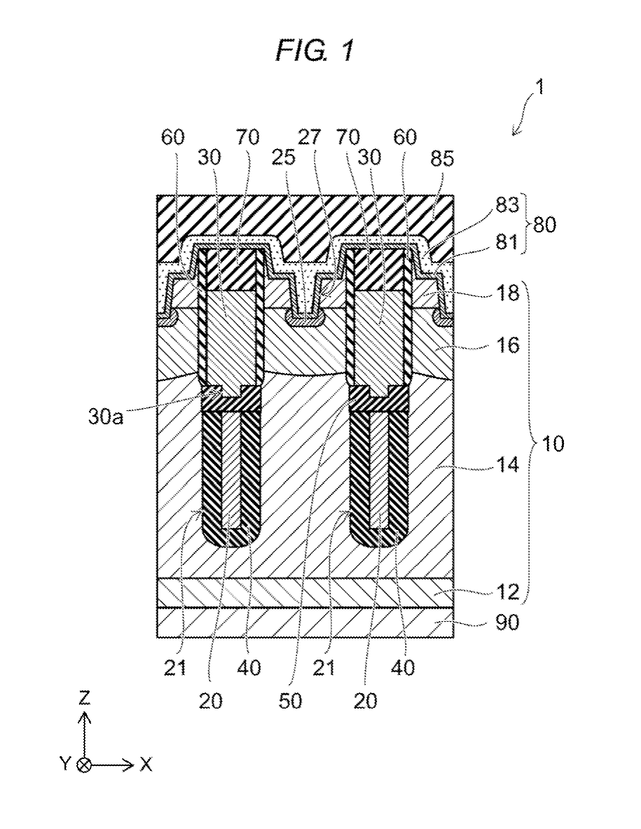

FIG. 1 is a cross-section view schematically exemplifying a semiconductor device 1 according to the embodiment. The semiconductor device 1 is, for example, a power MOSFET having a trench gate structure.

As illustrated in FIG. 1, the semiconductor device 1 includes, a semiconductor layer 10, a first electrode (hereinafter, a FP electrode 20), and a second electrode (hereinafter, agate electrode 30). The semiconductor layer 10 is, for example, a silicon layer provided on a silicon substrate. In addition, the semiconductor layer 10 may be the silicon substrate.

The semiconductor layer 10 includes, for example, an n-type drain layer 12, an n-type drift layer 14, a p-type base layer 16, and an n-type source layer 18. The n-type drift layer 14 is formed on the n-type drain layer 12. The p-type base layer 16 is formed on the n-type drift layer 14. The n-type source layer 18 is selectively formed on portions of the p-type base layer 16.

The FP electrode 20 and the gate electrode 30 are disposed in the inner portion of a trench 21 which is formed in the semiconductor layer 10 and is located between adjacent n-type source layers 18. The trench 21 is formed with a depth sufficient to reach and extend inwardly of the n-type drift layer 14 from the top surface of the n-type source layer 18. The trench 21 also extends, for example, in the Y direction (into or out of the page).

The FP electrode 20 is disposed in the lower portion of the trench 21 and the gate electrode 30 is formed over the FP electrode 20. The FP electrode 20 and the gate electrode 30 respectively extend in the Y direction in the inner portion of the trench 21 (into or out of the page). The lower surface of the gate electrode 30 includes a convex portion (a protruding portion) 30a that extends toward the FP electrode 20.

The semiconductor device 1 further includes a first insulating film 40 located between the sides and lowermost portion of the FP electrode 20, a second insulating film 50 located over the FP electrode 20 and the upper terminus of the first insulating film 40, and a third insulating film 60 on the sidewalls of the trench above the second insulating film 50.

The first insulating film 40 is disposed between the semiconductor layer 10 and the FP electrode 20. That is, the first insulating film 40 covers a lower surface of the FP electrode 20 and the side surfaces thereof. The FP electrode 20 extends inwardly of the n-type drift layer 14 having the first insulating film 40 disposed therebetween.

The second insulating film 50 is disposed between the FP electrode 20 and the gate electrode 30. The second insulating film 50 covers a top surface of the FP electrode 20 and electrically insulates the FP electrode 20 from the gate electrode 30.

The third insulating film 60 is disposed on the side walls of the trench 21 and thus between the gate electrode 30 and the semiconductor layer 10. The gate electrode 30 is disposed in a portion of the n-type drift layer 14, the p-type base layer 16, and the n-type source layer 18 via the third insulating film 60. That is, the third insulating film 60 functions as the gate insulating film.

For example, a thickness of the first insulating film 40 is greater than that of the third insulating film 60. A thickness of the second insulating film 50 in the Z direction is greater than that of the third insulating film 60 in the X direction. In addition, a thickness of the second insulating film 50 in the Z direction may be greater than that of the first insulating film 40 in the X direction.

The semiconductor device 1 further includes a p-type contact layer 25, an interlayer insulating film 70, a source electrode 80, and a drain electrode 90.

The p-type contact layer 25 is selectively formed on and inwardly of the p-type base layer 16. The p-type contact layer 25 is, for example, formed on the bottom of a trench 27 which extends inwardly of the p-type base layer between, in the X direction, adjacent n-type source layers 18. The interlayer insulating film 70 is provided over the gate electrode 30 in a region between the n-type source layers 18. The p-type contact layer 25 includes p-type dopants in a concentration that is greater than a concentration of dopants in the p-type base layer 16. The p-type contact layer 25 reduces the contact resistance of the semiconductor layer 10 with the source electrode 80. The interlayer insulating film 70 electrically insulates the gate electrode 30 from the source electrode 80. The source electrode 80 covers the interlayer insulating film 70 and is in electrical contact with the n-type source layer 18 and the p-type contact layer 25. The source electrode 80 is electrically connected to, for example, the FP electrode 20 by an element not illustrated in the drawing (e.g., the source electrode 80, the n-type source layer 18 and the p-type contact layer 25 are at the same potential). The source electrode 80 has, for example, a two-layer structure including a barrier metal 81 and a metal film 83. The barrier metal 81 is provided on the interlayer insulating film 70, the n-type source layer 18, and the p-type contact layer 25. The metal film 83 is provided on the barrier metal 81. A protective film 85 is provided over the source electrode 80.

A drain electrode 90 is electrically connected to the n-type drain layer 12. The drain electrode 90 is in electrical contact with, for example, the lower surface of the n-type drain layer 12. That is, the n-type drain layer 12 is positioned between the drain electrode 90 and the n-type drift layer 14.

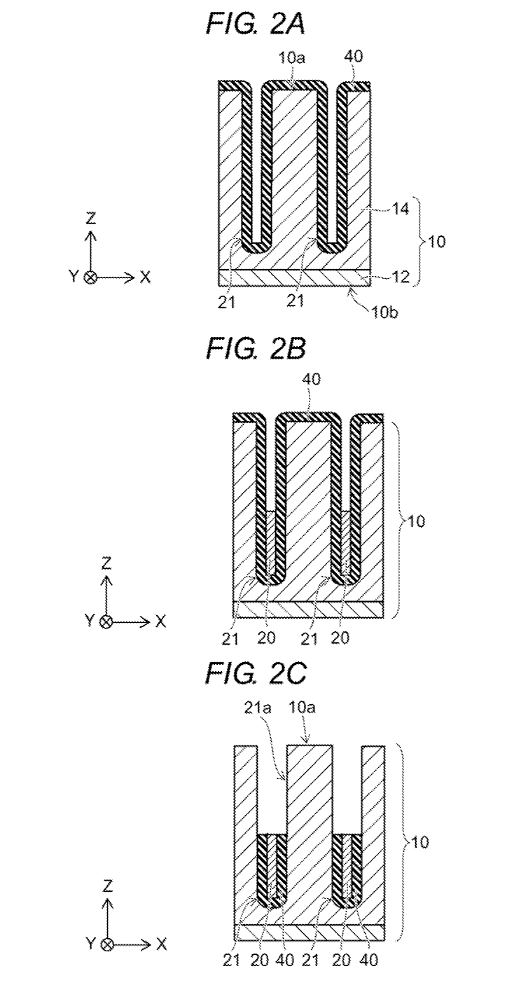

Next, with reference to FIG. 2A to FIG. 5C, the manufacturing method of the semiconductor device 1 will be described. FIG. 2A to FIG. 5C are cross-section views schematically exemplifying the manufacturing process of the semiconductor device 1.

As illustrated in FIG. 2A, the trench 21 is formed in a direction extending from a top surface 10a to a lower surface 10b of the semiconductor layer 10 and terminates within the n-type drift layer. The semiconductor layer 10 includes, for example, the n-type drain layer 12 and the n-type drift layer 14. The trench 21 also extends, for example, in the Y direction (into or out of the page). Sequentially, the first insulating film 40 is formed so as to cover the inner surface of the trench 21 and the top surface of the semiconductor layer 10. The first insulating film 40 is, for example, a silicon oxide film formed by a chemical vapor deposition (CVD) method.

As illustrated in FIG. 2B, the FP electrode 20 is formed on the lower portion of the trench 21. For example, an electrically conductive polysilicon film (not illustrated) is formed on the first insulating film 40 and in the inner portion of the trench 21. Subsequently, the polysilicon film is etched with a chemistry selective to the material of the conductive polysilicon material to leave a portion thereof corresponding to the FP electrode 20 in the lower portion of the trench 21.

As illustrated in FIG. 2C, the first insulating film 40 is then etched and a side wall 21a on the upper portion of the trench 21 and the top surface 10a of the semiconductor layer 10 are exposed. The first insulating film 40 is etched to leave in place a portion thereof disposed between the FP electrode 20 and the semiconductor layer 10, thus leaving uncovered the sidewalls of the trench 21 above the FP electrode 20. The first insulating film 40 may be removed by, for example, an isotropic dry etching method selective to the first insulating film material.

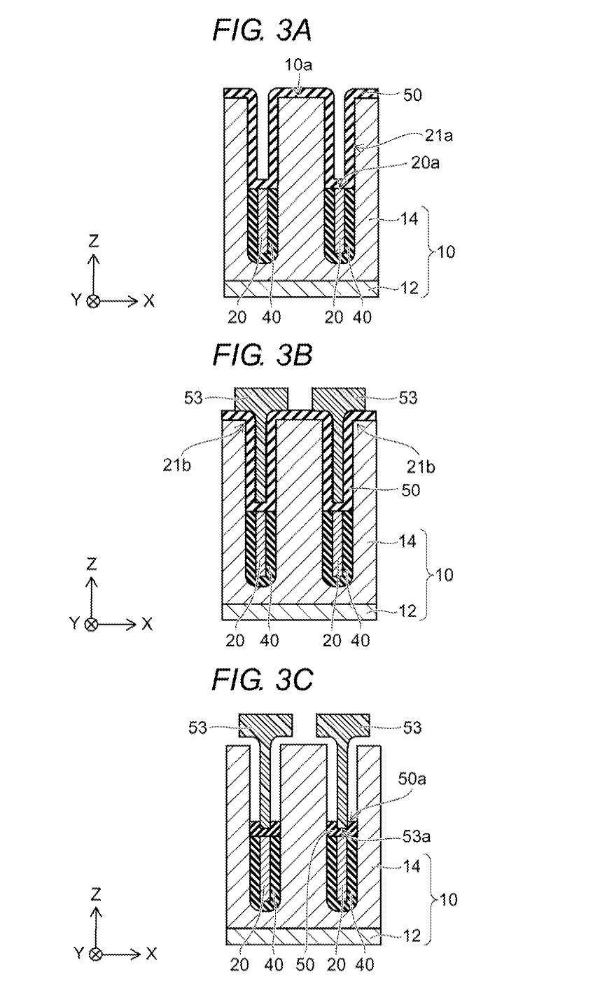

As illustrated in FIG. 3A, the second insulating film 50 is formed so as to cover a top surface 20a of the FP electrode 20, the side wall 21a of the trench 21, and the top surface 10a of the semiconductor layer 10. The second insulating film 50 is a silicon oxide film formed by, for example, the CVD method.

As illustrated in FIG. 3B, a resist film 53 is then formed on the second insulating film 50. The resist film 53 is embedded in the inner portion of the trench 21 and covers the upper portion of the trench 21.

As illustrated in FIG. 3C, the resist film 53 is used as a mask and the second insulating film 50 is then etched. That is, the portion of the second insulating film 50 which is formed on the top surface 10a of the semiconductor layer 10 is removed, and the portion of the second insulating film 50 formed between the side wall 21a of the trench 21 and the resist film. 53 is also etched away. For this reason, the side wall 21a of the trench 21 and the top surface 10a of the semiconductor layer 10 are exposed to leave a portion of the second insulating film 50 which is formed on the FP electrode 20 exposed. The etching is terminated such that an upper end 50a of the second insulating film 50 which remains on the FP electrode 20 is positioned above, in the Z direction, the lower end 53a of the resist film 53.

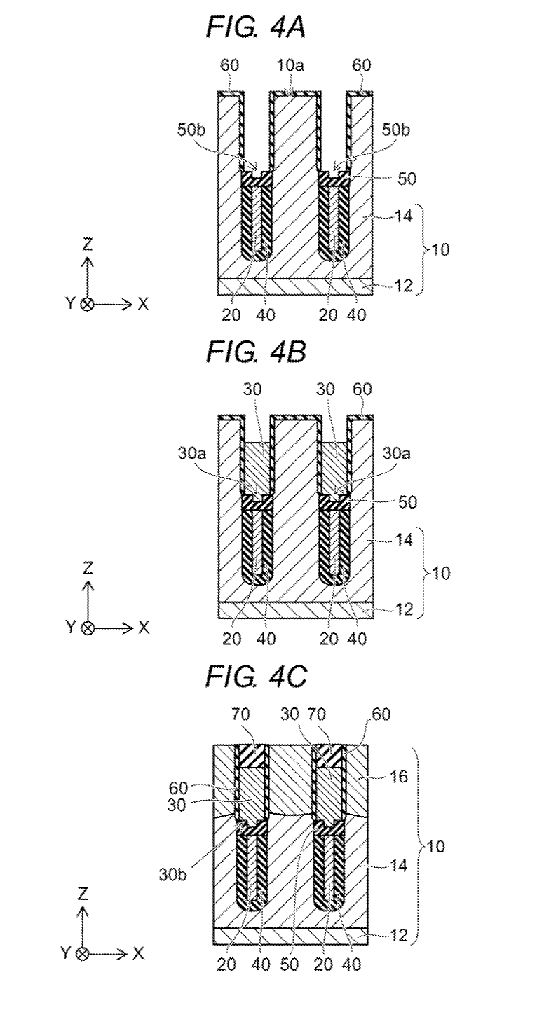

As illustrated in FIG. 4A, after the resist film 53 is removed, and the second insulating film 50 includes a depression 50b that aligns with the FP electrode 20 in the Z direction. Subsequently, the remaining resist film 53 is stripped off, and the third insulating film 60 is formed on the side wall 21a of the trench 21 and the top surface 10a of the semiconductor layer 10. The third insulating film 60 is, for example, a silicon oxide film. The third insulating film 60 is selectively formed by performing thermal oxidation on the semiconductor layer 10, for example.

As illustrated in FIG. 4B, the gate electrode 30 is then formed on the upper portion of the trench 21. The gate electrode 30 is formed, for example, by providing an electrically conductive polysilicon film (not illustrated) on the second insulating film 50 and the third insulating film 60 and embedded in the upper portion of the trench 21. Subsequently, the polysilicon film is etched to leave a portion corresponding to the gate electrode 30 on the upper portion of the trench 21. The gate electrode 30 also extends inwardly of the depression 50b in the second insulating film 50. As a result, the gate electrode 30 includes a protruding portion 30a facing the FP electrode 20 on a lower surface 30b thereof.

As illustrated in FIG. 4C, the interlayer insulating film 70 is formed on the gate electrode 30. The interlayer insulating film 70 is, for example, a silicon oxide film. Subsequently, the p-type base layer 16 is formed on the n-type drift layer 14. The p-type base layer 16 is formed by performing ion implantation of boron (B), which is one of the p-type dopants, into the top surface 10a of the semiconductor layer 10 and then performing a heat treatment, for example. A lower surface of the p-type base layer 16 is formed so as to be positioned above a plane of the lower surface 30b of the gate electrode 30 (in the X direction).

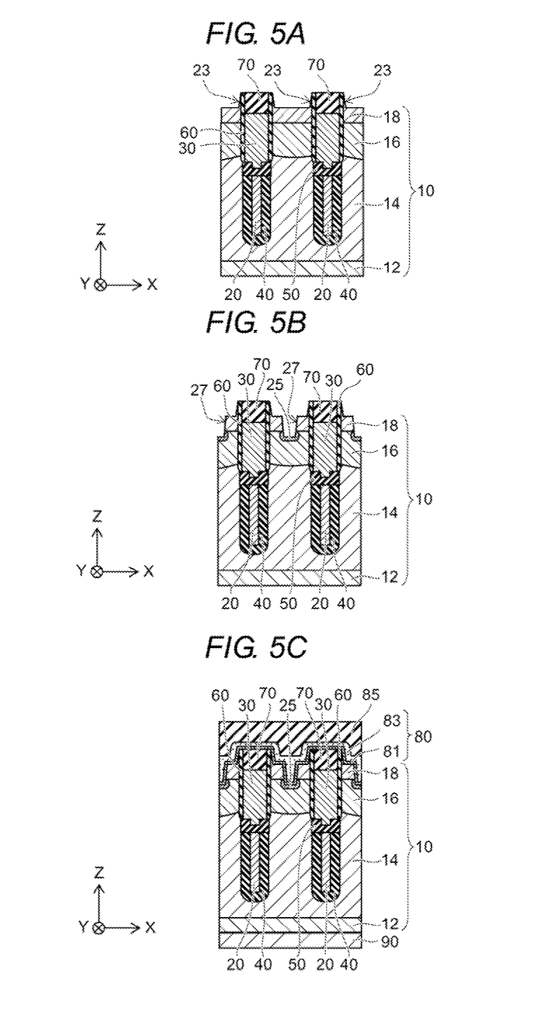

As illustrated in FIG. 5A, a recess portion 23 is formed on the top surface of the p-type base layer 16 and thereafter, the n-type source layer 18 is formed on the p-type base layer 16. The n-type source layer 18 is formed by ion implantation of arsenic (As), which is one of the n-type dopants, on a surface of the recess portion 23 and then performing a heat treatment, for example.

As illustrated in FIG. 5B, the p-type contact layer 25 is selectively formed on the p-type base layer 16. For example, the trench 27 is formed into the n-type source layer 18 and ion implantation of boron, which is one of the p-type dopants, is performed on the bottom of the trench 27. Thereafter, the p-type contact layer 25 is formed by a heat treatment to diffuse the dopants within the p-type base layer 16 to form the p-type contact layer. The trench 27 is provided, for example, between the gate electrodes 30, which are adjacent to each other, and the depth thereof (in the Z direction) is sufficient to reach, and extend slightly inwardly of, the p-type base layer 16 from the top surface of the n-type source layer 18.

As illustrated in FIG. 5C, the source electrode 80 is formed. The source electrode 80 includes, for example, the barrier metal 81 and the metal film 83. The barrier metal 81 covers the interlayer insulating film 70 and is in electrical contact with the n-type source layer 18 and the p-type contact layer 25. The metal film 83 covers the barrier metal 81. The barrier metal 81 is, for example, a titanium nitride (TiN) material. The metal film 83 is, for example, an aluminum film.

Further, the protective film 85 covering the source electrode 80 and the drain electrode 90 are formed so as to complete the semiconductor device 1. The protective film 85 is, for example, a silicon oxide film. The drain electrode 90 is formed so as be in electrical contact with, for example, the lower surface of the n-type drain layer 12. The drain electrode 90 may be, for example, a metal silicide.

As described above, the semiconductor device 1 is provided with the second insulating film 50 between the FP electrode 20 and the gate electrode 30. The second insulating film 50 includes depression on the upper side of the FP electrode 20 and a protruding portion formed on the lower surface of the gate electrode 30 faces the FP electrode 20.

The second insulating film 50 is formed solely to electrically insulate the FP electrode 20 from the gate electrode 30. Therefore, the thickness of the second insulating film 50 in the Z direction may be independently optimized in comparison to other insulating film layers in the device. For example, in order to reduce parasitic capacitance between the FP electrode 20 and the gate electrode 30, the thickness of the second insulating film in the Z direction may be provided to be greater than that of the thickness of the gate insulating film (the third insulating film 60) in the X direction. In addition, the thickness of the second insulating film in the Z direction may be provided to be greater than the thickness of the first insulating film 40 in the X direction.

The second insulating film 50 may have different properties as compared to, for example, the first insulating film 40 or the third insulating film 60. For example, the second insulating film 50, which is formed by the CVD method, has a greater hydrogen concentration than that of the third insulating film 60, which is formed by performing thermal oxidation. For example, hydrogen atoms of a source gas are incorporated into the insulating film when it is formed by the CVD method. For this reason, the concentration of the hydrogen atom in the film may be greater than that of an insulating film which is formed using a the thermal oxidation method. In the CVD method, the film may be formed at a low temperature as compared to a film formed by a thermal oxidation method and thus it is possible to reduce stress generated in the film. In this manner, for example, it is possible to prevent a wafer from being warped and thus to increase the manufacturing yield. In addition, if the CVD method is used, it is possible to easily form the thicker film compared with the thermal oxidation method.

Different materials from the first insulating film 40 or the third insulating film 60 may be used as the second insulating film 50.

In the semiconductor device 1 according to the embodiment, for example, the FP electrode 20 is not subjected to thermal oxidation. Therefore, the controllability of the position of the upper end of the FP electrode 20 with respect to the layers formed on or in the semiconductor layer 10 is enhanced. In addition, it is possible forma relatively thick second insulating film 50 between the FP electrode 20 and the gate electrode 30, thereby increasing the electrical insulation property provided thereby. Accordingly, the reliability of the semiconductor device 1 may be improved. Further, the process of forming the insulating film between the FP electrode 20 and the gate electrode 30 is simplified, and thereby it is possible to achieve a significant reduction in the manufacturing process.

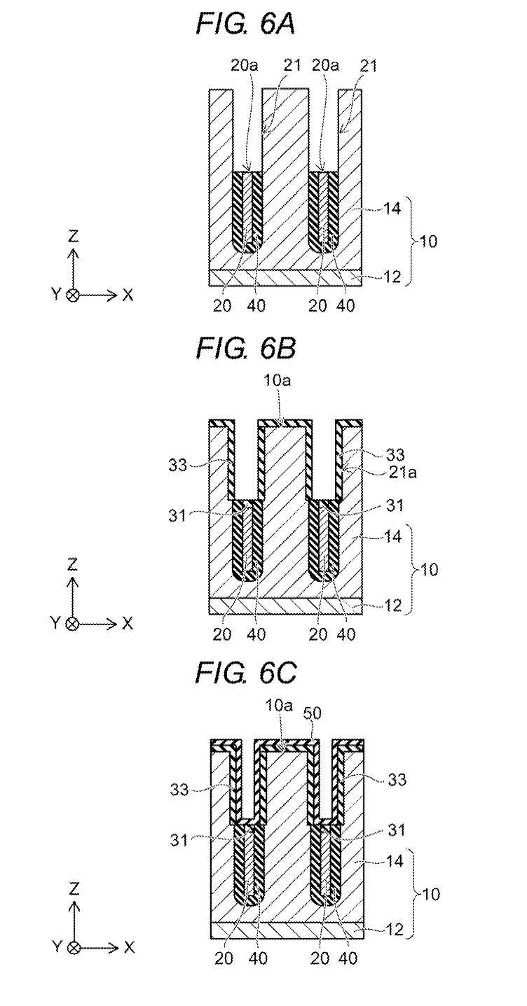

Next, with reference to FIG. 6A to FIG. 6C, a manufacturing method of the semiconductor device 1 according to a modification modified example of the embodiment will be described. FIG. 6A to FIG. 6C are schematic cross-sectional views schematically exemplifying a manufacturing process according to the modified example.

As illustrated in FIG. 6A, the FP electrode 20 is formed on the lower portion of the trench 21. The FP electrode 20 is formed over the first insulating film 40 lining the surface of the trench 21 and in contact with the semiconductor layer 21. The first insulating film 40 covers the side surfaces and the lower surface of the FP electrode 20 and the trench 21. The top surface 20a of the FP electrode 20 is exposed to the inner surface of the upper portion of the trench 21.

As illustrated in FIG. 6B, the top surface 20a of the FP electrode 20 and the surface of the semiconductor layer 10, including the walls of the trench 21 above the FP electrode 20, are subjected to the thermal oxidation. As a result, an insulating film 31 is formed on the FP electrode 20 in situ. The insulating film 31 is, for example, a silicon oxide film obtained by performing a thermal oxidation process on the upper end of the silicon of the FP electrode 20. In addition, an insulating film 33 is formed on the side wall 21a of the trench 21 and the top surface 10a of the semiconductor layer 10. The insulating film 33 is, for example, the silicon oxide film obtained by performing the thermal oxidation process on the silicon layer 10.

As illustrates in FIG. 6C, a second insulating film 50 is formed on the insulating films 31 and 33. The second insulating film 50 is formed by, for example, the CVD method. The second insulating film 50 covers the side walls of the upper portion of the trench 21 and the top surface of the semiconductor layer 10, as well as the oxide layer 31 formed at the top of the FP electrode 20.

Further, the completion of the semiconductor device 1 is provided by performing the processes described in FIG. 3B and the subsequent drawing figures. In this example, it is possible to interpose an insulating film 31 (the thermal oxidation film) between the second insulating film 50 and the FP electrode 20. In this way, it is possible to further thicken the total thickness of the insulating films, films 31 and 33, between the FP electrode 20 and the gate electrode 30, thereby further reducing a parasitic capacitance therebetween.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
forming a first electrode in a lower portion of a trench that extending inwardly of a semiconductor layer and on a first insulating film disposed between the first electrode and the semiconductor layer;
forming a second insulating film on an inner surface of an upper portion of the trench;
forming a resist film in the upper portion of the trench and on the second insulating film;
removing the second insulating film between the resist film and a side wall of the trench to leave a portion of the second insulating film on the first electrode;
forming a third insulating film on a side wall of an upper portion of the trench; and
forming a second electrode on the first electrode in an inner portion of the trench and over the second insulating film.

2. The method according to claim 1, further comprising:
performing thermal oxidation on an upper end of the first electrode.

3. The method according to claim 2,
wherein the second insulating film is selectively removed so that an upper end portion of the second insulating film is positioned above a lower end of the resist film in the inner portion of the second insulating film.

4. The method according to claim 3, wherein
the second insulating film includes a depressed portion adjacent an upper side of the first electrode, and
the second electrode is formed so that a portion of the second electrode extends into the depressed portion.

5. The method according to claim 1,
wherein the second insulating film is selectively removed so that an upper end portion of the second insulating film is positioned above a lower end of the resist film in the inner portion of the second insulating film.

6. The method according to claim 5, wherein
the second insulating film includes a depressed portion adjacent an upper side of the first electrode, and
the second electrode is formed so that a portion of the second electrode extends into the depressed portion.

7. The method according to claim 1, wherein
the second insulating film includes a depressed portion on an upper side of the first electrode, and
the second electrode is formed so that a portion of the second electrode extends into the depressed portion.

8. The method according to claim 1,
wherein the second insulating film includes a hydrogen concentration that is greater than a hydrogen concentration of one or both of the first insulating film and the third insulating film.

9. The method according to claim 1,
wherein the second insulating film includes a thickness that is greater than a thickness of one or both of the first insulating film and the third insulating film.

10. A manufacturing method of a semiconductor device, comprising:
forming a first electrode in a lower portion of a trench which is formed on a semiconductor layer and on a first insulating film between the first electrode and the semiconductor layer;
forming a second insulating film that covers an inner surface of an upper portion of the trench;
removing the second insulating film on a side wall of the upper portion of the trench to leave a portion of the second insulating film on the first electrode;
forming a third insulating film on the side wall of the upper portion of the trench; and
forming a second electrode on the first electrode in an inner portion of the second insulating film.

11. The method according to claim 10, further comprising:
performing thermal oxidation on an upper end of the first electrode.

12. The method according to claim 11, wherein
the second insulating film includes a depressed portion adjacent an upper side of the first electrode, and
the second electrode is formed so that a portion of the second electrode extends into the depressed portion.

13. The method according to claim 10, wherein
the second insulating film includes a depressed portion on an upper side of the first electrode, and
the second electrode is formed so that a portion of the second electrode extends into the depressed portion.

14. The method according to claim 10,
wherein the second insulating film includes a hydrogen concentration that is greater than a hydrogen concentration of one or both of the first insulating film and the third insulating film.

15. The method according to claim 10,
wherein the second insulating film includes a thickness that is greater than a thickness of one or both of the first insulating film and the third insulating film.

16. A semiconductor device comprising:
a semiconductor layer;
a first electrode that is provided in a first trench in the semiconductor layer;
a second electrode that is provided in the first trench on the first electrode in the semiconductor layer, the second electrode including a protruding portion extending toward the first electrode;
a first insulating film that is provided between the first electrode and the semiconductor layer;
a second insulating film that is provided between the first electrode and the protruding portion; and
a third insulating film that is provided between the second electrode and the semiconductor layer,
wherein the second insulating film has a hydrogen concentration that is greater than a hydrogen concentration of the third insulating film.

17. The semiconductor device of claim 16,
wherein a thickness of the second insulating film is greater than a thickness of one or both of the first insulating film and the third insulating film.

18. The semiconductor device of claim 16,
wherein the second insulating film includes a depressed portion adjacent an upper side of the first electrode.

19. The semiconductor device of claim 18,
wherein the protruding portion extends into the depressed portion.

20. The semiconductor device of claim 16,
further comprising a plurality of first trenches and a second trench is formed between adjacent first trenches.
